(19) United States
(12) Patent Application Publication
(10) Pub. No.: US 2016/0309597 A1
(43) Pub. Date: Oct. 20, 2016

(54) FIXING STRUCTURE FOR BACK COVER AND FRONT FRAME OF DISPLAY DEVICE

(71) Applicant: HON HAI PRECISION INDUSTRY CO., LTD., New Taipei (TW)

(72) Inventors: JEN-HUI OH, New Taipei (TW); CHING-HUA TSAI, New Taipei (TW)

(21) Appl. No.: 14/718,987

(22) Filed: May 21, 2015

(30) Foreign Application Priority Data
Apr. 15, 2015 (TW) 104112149

(51) Int. Cl. H05K 5/00; H05K 5/02

(52) U.S. Cl. CPC H05K 5/0017; H05K 5/0008; H05K 5/0217

(57) ABSTRACT

A display device includes a front frame, a back cover, and a display panel. The front frame includes a plurality of limiting grooves. The back cover includes a plurality of positioning rods corresponding with the limiting grooves. The display panel is fixed between the front frame and the back cover. The back cover is fixed to the front frame by an engagement action between the limiting grooves and the positioning rods.

### CROSS-REFERENCE TO RELATED APPLICATIONS

This application claims priority to Taiwanese Patent Application No. 104112149 filed on Apr. 15, 2015, the contents of which are incorporated by reference herein.

### FIELD

The subject matter herein generally relates to a fixing structure for a back cover and a front frame of a display device.

### BACKGROUND

Generally, a display device, such as a liquid crystal device (LCD) can include a back cover, a front frame, and a display panel fixed between the back cover and the front frame.

### BRIEF DESCRIPTION OF THE DRAWINGS

Implementations of the present technology will now be described, by way of example only, with reference to the attached figures.

FIG. 1 is an isometric view of a display device.

FIG. 2 is an exploded view of the display device of FIG. 1.

FIG. 3 is an enlarged view of a circled region III in FIG. 2.

FIG. 4 is a diagrammatic view of a first frame of the display device of FIG. 2.

FIG. 5 is a diagrammatic view of a third frame of the display device of FIG. 2.

FIG. 6 is a diagrammatic view of a second frame and a fourth frame of the display device of FIG. 2.

FIG. 7 is an enlarged view of a circled region VI in FIG. 1.

FIG. 8 is a diagrammatic view of a coupled position between the first frame and the second frame of the display device, which is an enlarged view of a circled region VIII.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “coupled” is defined as connected, whether directly or indirectly through intervening components, and is not necessarily limited to physical connections. The connection can be such that the objects are permanently connected or releasably connected. The term “comprising”, when utilized, means “including, but not necessarily limited to”; it specifically indicates open-ended inclusion or membership in the so-described combination, group, series and the like.

The present disclosure is described in relation to a fixing structure for a back cover and a front frame of a display device.

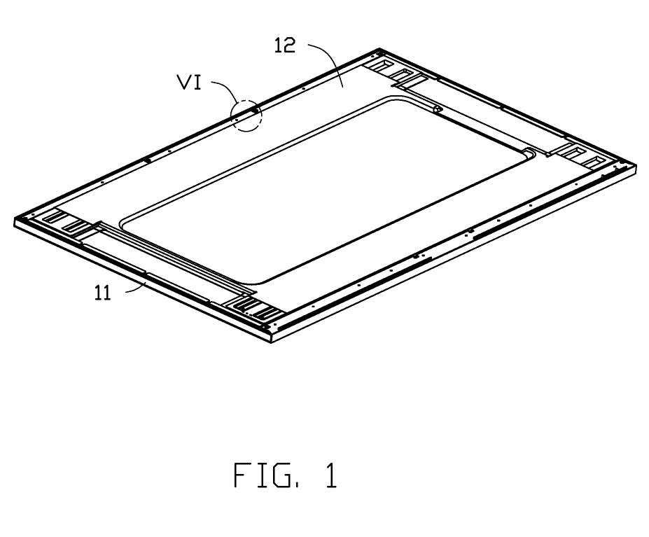

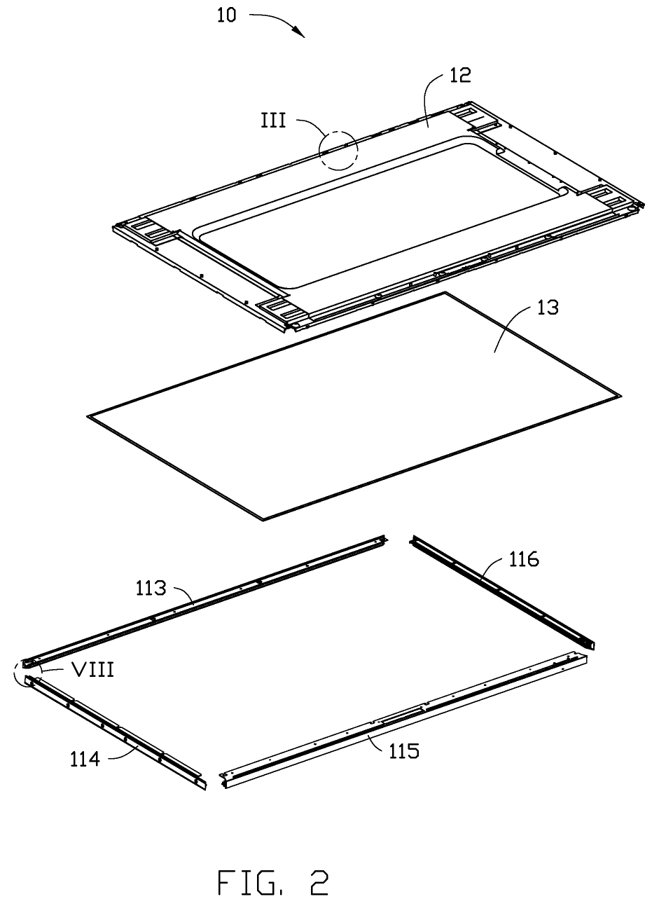

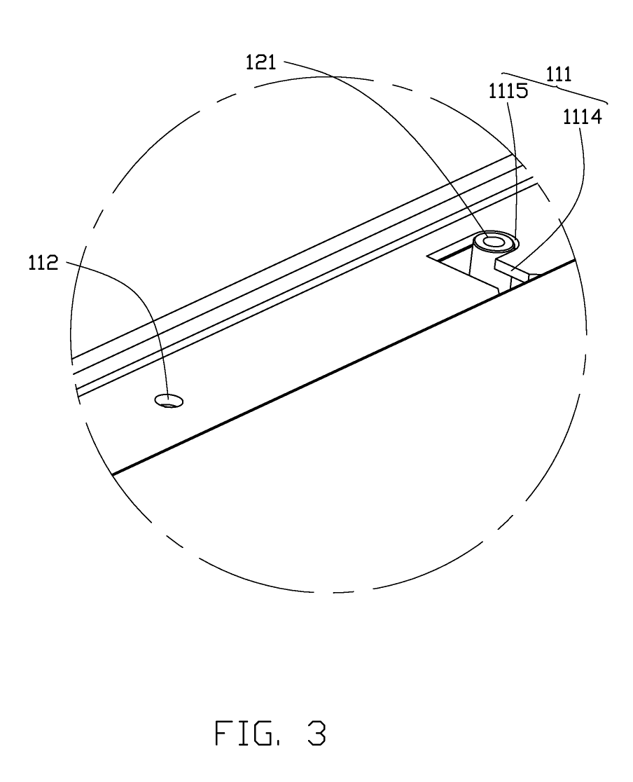

Referring to FIG. 1 to FIG. 3. FIG. 1 is an isometric view of a display device 10, FIG. 2 is an exploded view of the display device 10 of FIG. 1, FIG. 3 is an enlarged view of a circled region III of the display device 10 in FIG. 2. The display device 10 can include a front frame 11, a back cover 12, and a display panel 13 fixed between the front frame 11 and the back cover 12. The display device 10 can be a television, a computer monitor, or other like device.

The front frame 11 includes a plurality of limiting grooves 111. The back cover 12 includes a plurality of positioning rods 121 to couple with the limiting grooves 111. The front frame 11 the back cover 12 are fixed to each other via the engagement between the limiting grooves 111 and the positioning rods 121. The positioning rods 121 are hollow cylinders integrally disposed on the back cover 12. The front frame 11 further includes a plurality of first screw holes 112. Each two first screw holes 112 are located between two adjacent positioning rods 121. The back cover 12 further includes a plurality of second screw holes 122 corresponding with the plurality of first screw holes 112. Thus, the front frame 11 can be fixed to the back cover 12 by a plurality of screws. Each of the screws passes through a corresponding first screw hole 112 and a corresponding second screw hole 122 to fix the front frame 11 and the back cover 12.

In at least one embodiment, the front frame 11 can be metal frame or a plastic frame. The back cover 12 can be metal cover or a plastic cover.

The front frame 11 can include a first frame 113, a second frame 114, a third frame 115, and a fourth frame 116 coupled end to end. The first frame 113 is opposite to the third frame 115. The second frame 114 is opposite to the fourth frame 116. The first frame 113 and the third frame 115 are arranged in parallel, and the second frame 114 and the fourth frame 116 are arranged in parallel. A length of the first frame 113 can be equal to that of the third frame 115, and a length of the second frame 114 can be equal to that of the fourth frame 116. The length of the first frame 113 or the third frame 115 can be different than the length of the second frame 114 or the fourth frame 116. For example, the length of the first frame 113 (or third frame 115) is greater than the length of the second frame 114 (or fourth frame 116). In at least embodiment, the front frame 11 can be detachable structure formed by the first, second, third, and fourth frames 113-116.

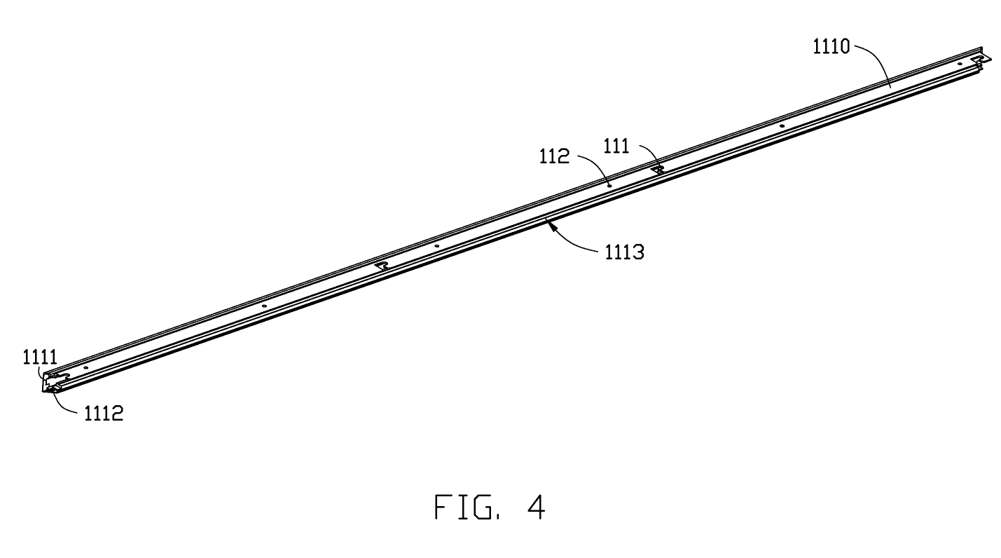

FIG. 4 illustrates a diagrammatic view of the first frame 113 of the display device 10 of FIG. 2. The first frame 113 includes a first sidewall 1110, a second sidewall 1111, and a third sidewall 1112. The first sidewall 1110 is opposite to the third sidewall 1112. The second sidewall 1111 is connected between the first sidewall 1110 and the third sidewall 1112. In the embodiment, the first, second, and third sidewalls 1110, 1111, 1112 jointly form a groove to receive an edge of the display panel 13.

Some of the limiting grooves 111 and the first screw holes 112 are located on the third sidewall 1112. In at least one embodiment, the limiting groove 111 includes a guiding portion 1114 and a limiting portion 1115 coupled with the guiding portion 1114. The guiding portion 114 extends along a first direction, and the limiting portion 1115 extends along a second direction perpendicular to the first direction. Thus, the guiding portion 114 and the limiting portion 1115 jointly form an L-shaped limiting groove 111. The limiting portion 1115 is latched to a corresponding positioning rod 121. In this embodiment, a width of the guiding portion 1114 is greater than that of the limiting portion 1115. A width of the limiting portion 1115 is substantially equal to a diameter of the limiting rod 121. The limiting portion 1115 has a semi-arc terminal to latch the limiting rod 121.

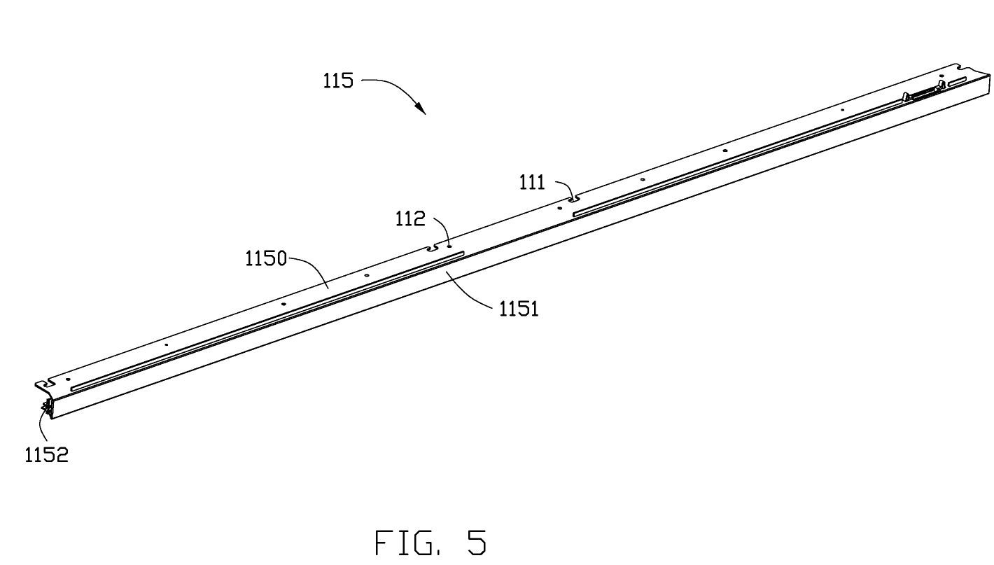

FIG. 5 illustrates a diagrammatic view of the third frame 1115 of the front frame 11. The third frame 115 has substantially the same structure as the first frame 113. The third frame 115 includes a first sidewall 1150, a second sidewall 1151, and a third sidewall 1152. The first sidewall 1150 is opposite to the third sidewall 1152. The second sidewall 1151 is connected between the first sidewall 1150 and the third sidewall 1152. In the embodiment, the first, second, and third sidewalls 1150, 1151, 1152 jointly form a groove to receive an edge of the display panel 13. Some of the limiting grooves 111 and the first screw holes 112 are located on the third sidewall 1152. In at least one embodiment, the limiting grooves 111 located on the third sidewall 1152 of the third frame 115 are mirror symmetrical to the limiting grooves 111 located on the third sidewall 1112 of the first frame 113.

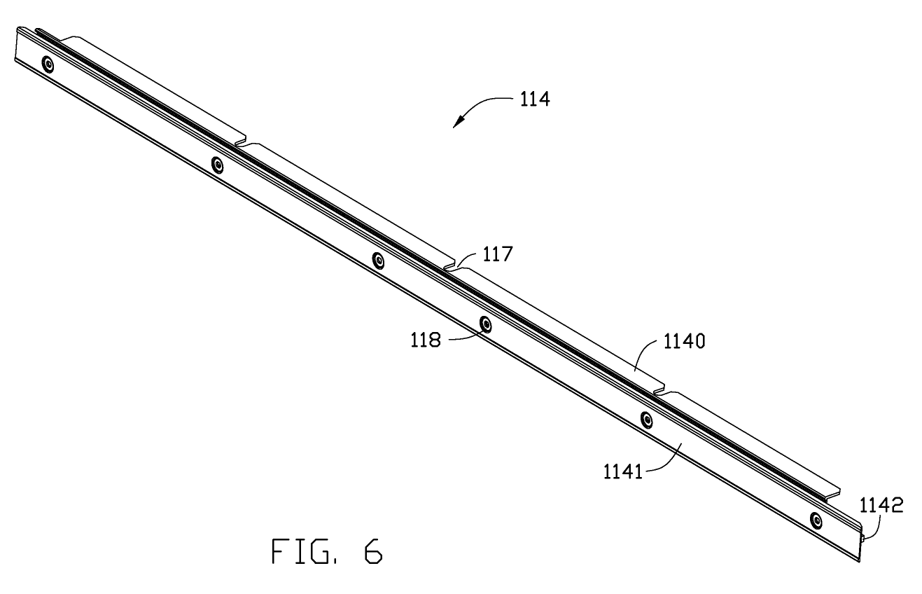

The second frame 114 and the fourth frame 116 have substantially the same structures. FIG. 6 illustrates the second frame 114 includes a first sidewall 1140, a second sidewall 1141, and a third sidewall 1142. The first sidewall 1140 is opposite to the third sidewall 142 and is parallel to the third sidewall 1142. The second sidewall 1141 is coupled between the first sidewall 1140 and the third sidewall 1142. The third sidewall 1142 defines a plurality of receiving grooves 117. The second sidewall 1141 defines a plurality of through holes 118.

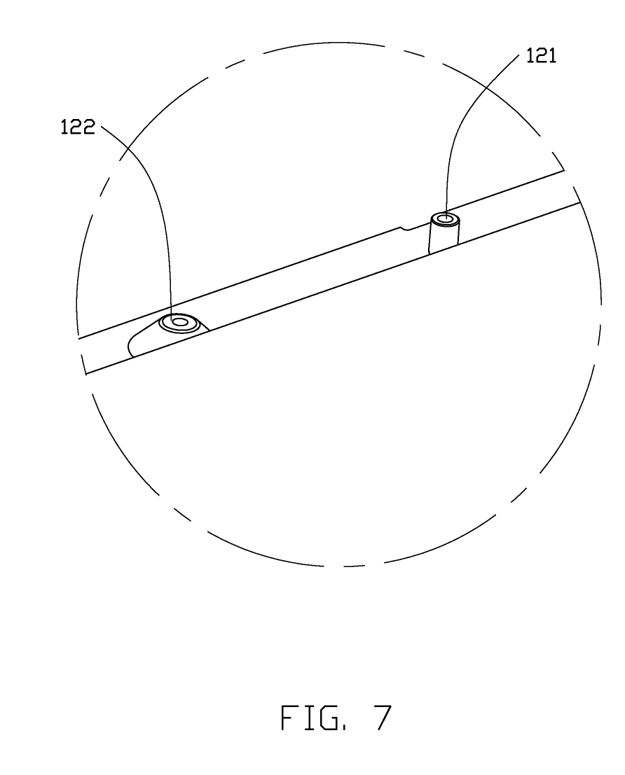

FIG. 7 illustrates an enlarged view of a circled region VII in FIG. 1. The positioning rod 121 is located at the edge of the back cover 12 corresponding with the limiting groove 111 to be latched into the limiting portion 1115 of a corresponding limiting groove 111. The second screw hole 122 is located at the edge of the back cover 12 corresponding with the first screw hole 112 to allow a corresponding screw to pass through. Further, the second frame 114 and the fourth frame 16 can be fixed to the back cover 12 via the through holes 118.

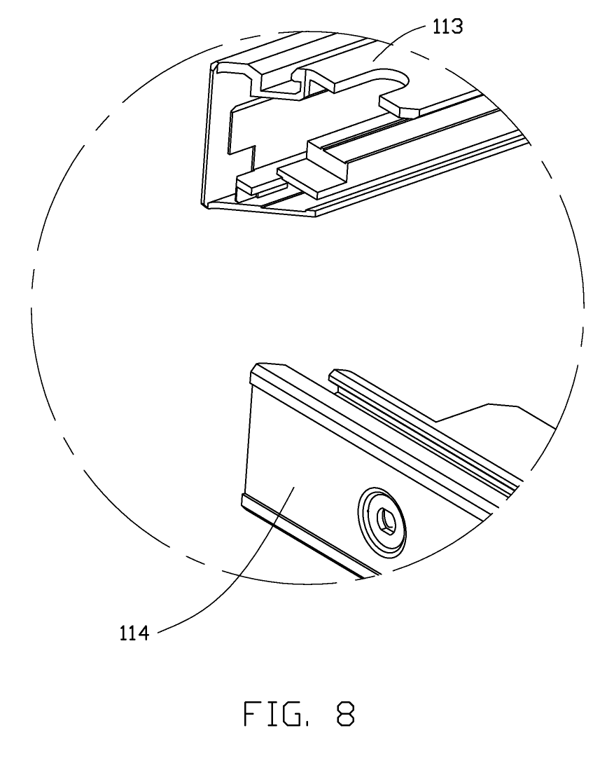

FIG. 8 illustrates a diagrammatic view of a coupled position VIII between the first frame 113 and the second frame 114 in FIG. 2. In at least one embodiment, at the coupled position between the first frame 113 and the second frame 114, each of the first frame 113 and the second frame 114 includes at least one wedge-shaped surface to fit the first frame 113 to the second frame 114. Accordingly, at the coupled position between the second frame 114 and the third frame 115, each of the second frame 114 and the third frame 115 includes at least one wedge-shaped surface to fit the second frame 114 to the third frame 115. At the coupled position between the third frame 115 and the fourth frame 116, each of the third frame 115 and the fourth frame 116 includes at least one wedge-shaped surface to fit the third frame 115 to the fourth frame 116. At the coupled position between the fourth frame 116 and the first frame 113, each of the fourth frame 116 and the first frame 113 includes at least one wedge-shaped surface to fit the fourth frame 116 to the first frame 113. The at least one wedge-shaped surface can be formed by diamond cutting process.

In assembly, some of the positioning rods 121 of the back cover 121 are respectively inserted into the guiding portions 1114 of the limiting grooves 111 on the first frame 113, and the back cover 12 is moved to respectively latch the limiting rods 121 into the limiting portions 1115 of the limiting grooves 111. Then, the first frame 113 is threadedly engaged with the back cover 12 by screws.

Further, the other positioning rods 121 of the back cover are respectively inserted into the guiding portions 1114 of the limiting grooves 111 on the third frame 115, and the back cover 12 is moved to respectively latch the limiting rods 121 into the limiting portions 115 of the limiting grooves 111. Then, the third frame 115 is threadedly engaged with the back cover 12 by screws as well as the first frame 113.

At last, the second frame 114 and the fourth frame 116 can be threadedly engaged with the back cover 12 by screws passing through the through holes 118, respectively.

As described above, the front frame 11 and the back cover 12 of the display device 10 can be fixed with each other using limiting grooves 111 defined on the front frames 11 and limiting rods 121 defined on the back cover 12. Thus, facilitating the detachment of the front frame 11 from the back cover 12.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

1. A display device comprising:
a front frame comprising a plurality of limiting grooves each passing through two opposite surfaces of the front frame;
a back cover comprising a plurality of positioning rods corresponding with the limiting grooves, each of the plurality of positioning rods being hollow cylinder; and
a display panel fixed between the front frame and the back cover,
wherein the back cover is fixed to the front frame by an engagement action between the limiting grooves and the positioning rods.

2. The display device according to claim 1, wherein the front frame further comprises a first frame, a second frame, a third frame, and a fourth frame coupled end to end, the first frame is opposite to the third frame, the second frame is opposite to the fourth frame, the first frame and the third frame are arranged in parallel, and the second frame and the fourth frame are arranged in parallel.

3. The display device according to claim 2, wherein a length of the first frame is equal to a length of the third frame, and a length of the second frame is equal to a length of the fourth frame.

4. The display device according to claim 3, wherein the length of the first frame or the third frame is greater than the length of the second frame or the fourth frame.

5. The display device according to claim 2, wherein some of the limiting grooves of the front frame are located on the first frame, and the other of the limiting grooves are located on the third frame, the limiting grooves located on the third frame are mirror symmetrical to the limiting grooves located on the first frame.

6. The display device according to claim 1, wherein each of the limiting grooves comprises a guiding portion and a limiting portion coupled with the guiding portion, each of the guiding portion and the limiting portion passes through the two opposite surfaces of the front frame, the guiding portion guides a corresponding positioning rode to be latched into the limiting portion.

7. The display device according to claim 6, wherein the guiding portion extends along a first direction parallel to the front frame, and the limiting portion extends along a second direction parallel to the front frame and perpendicular to the first direction, the guiding portion and the limiting portion jointly form an L-shaped limiting groove.

8. The display device according to claim 7, wherein a width of the guiding portion is greater than a width of the limiting portion, and a width of the limiting portion is equal to a diameter of the limiting rod.

9. The display device according to claim 7, wherein the limiting portion comprises an semi-arc terminal to latch the limiting rod.

10. The display device according to claim 2, wherein each of the first frame and the third frame comprises a first sidewall, a second sidewall, and a third sidewall, the first sidewall is opposite to the third sidewall, the second sidewall is coupled between the first sidewall and the third sidewall to form an receiving groove to receive an edge of the display panel.

11. The display device according to claim 10, wherein the limiting grooves are located on the third sidewall, the third sidewall defines a plurality of screw holes, and each two screw holes are located between two adjacent screw holes.

12. The display device according to claim 11, wherein the back cover defines a plurality of second screw holes corresponding with the plurality of first screw holes, and the first frame and the third frame are threadedly engaged with the back cover by screws respectively passing through a corresponding first screw hole and a corresponding second screw hole.

13. The display device according to claim 2, wherein each of the second frame and the fourth frame comprises a first sidewall, a second sidewall, and a third sidewall, the first sidewall is opposite to the third sidewall, the second sidewall is coupled between the first sidewall and the third sidewall to form an receiving groove to receive an edge of the display panel.

14. The display device according to claim 13, wherein the second side wall defines a plurality of through holes configured to threadedly fix the second frame and the fourth frame to the back cover via screws passing through the through holes.

15. A display device comprising:
a front frame comprising a plurality of limiting grooves each passing through two opposite surfaces of the front frame and a plurality of first screw holes; and
a back cover comprising a plurality of positioning rods corresponding with the limiting grooves and a plurality of second screw holes respectively corresponding with the first screw holes, each of the positioning rods being hollow cylinder and respectively latched into a corresponding one of the limiting grooves;
wherein the back cover is threadedly fixed to the front frame by screws respectively passing through a corresponding first screw hole and a corresponding second screw hole.

16. The display device according to claim 15, wherein the front frame further comprises a first frame, a second frame, a third frame, and a fourth frame coupled end to end, the first frame is opposite to the third frame, the second frame is opposite to the fourth frame, the first frame and the third frame are arranged in parallel, and the second frame and the fourth frame are arranged in parallel.

17. The display device according to claim 16, wherein some of the limiting grooves of the front frame are located on the first frame, and the other of the limiting grooves are located on the third frame, the limiting grooves located on the third frame are mirror symmetrical to the limiting grooves located on the first frame.

18. The display device according to claim 15, wherein each of the limiting grooves comprises a guiding portion and a limiting portion coupled with the guiding portion, each of the guiding portion and the limiting portion passes through the two opposite surfaces of the front frame, the guiding portion guides a corresponding positioning rode to be latched into the limiting portion.

19. The display device according to claim 18, wherein the guiding portion extends along a first direction parallel to the front frame, and the limiting portion extends along a second direction parallel to the front frame and perpendicular to the first direction, the guiding portion and the limiting portion jointly form an L-shaped limiting groove.

20. The display device according to claim 18, wherein the limiting portion comprises an semi-arc terminal to latch the limiting rod.
